(19) United States
(12) Patent Application Publication
(10) Pub. No.: US 2017/0051411 A1
(43) Pub. Date: Feb. 23, 2017

(54) Electroless Silver Plating Bath and Method of Using the Same

(71) Applicant: MacDermid Acumen, Inc., Waterbury, CT (US)

(72) Inventors: Jordan Kologe, Thomaston, CT (US); Lei Jin, Unionville, CT (US); Ernest Long, Burlington, CT (US); Alexander Konefal, Berlin, CT (US); Wei Yan, Waterbury, CT (US)

(21) Appl. No.: 14/831,403

(22) Filed: Aug. 20, 2015

(51) Int. Cl. C23C 18/32; H01L 33/62; H05K 3/18; C23C 18/16; C23C 18/42

(52) U.S. Cl. CPC C23C 18/32; C23C 18/1637; C23C 18/42; H05K 3/181; H01L 33/62; H01L 2933/0066

(57) ABSTRACT

An electroless silver plating bath and method of use is presented within. The electroless silver plating bath is designed to plate only on the desired metal substrate while preventing plating on areas other than those which are to be plated. The invention uses heavy metal based stabilizers in the electroless silver plating bath to prevent extraneous plating. The ability to control the amount of stabilizer present in the plating bath allows for elimination of extraneous plating and allows for a stable bath. The electroless silver plating bath is very stable and yet plates at an acceptable rate. The electroless silver plating bath prevents corrosion on the underlying metal that is plated on by using the stabilizers as described herein. The silver plating bath presented herein is useful for a wide variety of applications including those in electronic packaging, integrated circuits (IC) and in manufacturing of light emitting diodes (LEDs).

### FIELD OF THE INVENTION

The present invention relates generally to an electroless silver plating composition that is both stable and prevents extraneous plating. The invention uses heavy metal based stabilizers which are both measurable and controllable in solution. The process of plating on a substrate using the invention described herein substantially prevents plating in areas other than the metal surface where plating is desired. This invention provides for an autocatalytic reaction, opposed to the galvanic reaction that typically occurs between silver and the metal to be plated upon

### BACKGROUND OF THE INVENTION

There are several well-known methods for the plating of metals, such as electroplating, immersion plating and autocatalytic electroless plating. Among all the plating methods, autocatalytic electroless plating has the capability to plate a substantially uniform metallic coating onto a substrate having an irregular shape. Electroless coatings are also virtually nonporous, which allows for greater corrosion resistance than electroplated plated or immersion plated substrates. Thus, electroless plating methods are widely used in the printed circuit board (PCB), integrated circuit (IC), and light emitting diode (LED) industries. Most common plating methods involve electroless nickel plating, electroless copper plating, and electroless gold plating.

Plating a copper or copper alloy surface with electroless nickel followed by immersion gold (ENIG) is an industry standard that typically produces a reliable deposit that is useful in various applications. While ENIG has proven to be very reliable, it is not without issues. The gold plating step can be excessively corrosive to the nickel deposit causing deterioration of the nickel at the grain boundaries which compromises the integrity of the deposit. The gold plating step is additionally very expensive in comparison to other plating steps. Electroless silver plating has become a desirable alternative to plating immersion gold over nickel plated surfaces due to cost restraints and a desire to reduce potential corrosion at the grain boundaries found on the nickel surface. Black line nickel is a well-known issue within the industry when the traditional coating of ENIG is employed. Not only is silver an economically responsible choice over gold but a silver bath formulation that plates completely by an electroless mechanism (not by immersion/exchange reaction) is much less corrosive to the underlying metal surface. The electroless silver plated surface is additionally useful in applications such as LEDs where surface reflectivity is important.

Electroless silver plating is a well-known process. However, application of electroless silver plating in industries such as PCB, IC, and LED manufacturing is limited due to several fundamental issues of the process. Some of the issues are:

a) The plating baths tend to spontaneously decompose forming silver particles throughout the solution. This decomposition causes loosely adherent, very fine silver metal particles on the deposit and short bath life.

b) An immersion reaction occurs during plating due to the difference of reduction potential between Ag and the metal substrates, such as copper and nickel. This reaction causes severe metal substrate corrosion (see FIG. 1), which brings problems such as adhesion loss, poor solderability, and wirebond failures.

c) Undesirable extraneous Ag plating is a widely experienced problem (See FIG. 3). It is well known that electroless silver process has the tendency for the silver to plate not only on the desired metal substrate lines and pads, but also to deposit on portions of the dielectric substrate or insulator located between lines and pads. This problem is especially pronounced when dealing with very fine lines that are only separated by very small intervals, resulting bridging and short circuiting. Controlling the undesirable extraneous plating is a significant problem.

Although electroless silver technology is well known, electroless silver plating has not become a widely used commercial technology due to issues mentioned above.

There have been attempts to cure the problem of extraneous plating while maintaining a stable silver plating bath as set out in U.S. Pat. No. 5,322,553, US Patent Application 2012/0061698 A1, and International Publication WO 2006/065221 A1. These patents are hereby incorporated by reference in their entirety.

In U.S. Pat. No. 5,322,553 the inventors found that a thiosulfate salt in combination with a sulfite salt in an electroless silver plating solution allowed for a uniform deposit. By using this redox system there is no need for any additional type of reducing agent and the bath does not contain ammonia or cyanide ions. While the inventors show that a reasonable silver deposit may be plated over nickel, the bath is said to be sensitive to silver concentration such that if the concentration is out of the desired range then the bath is difficult to control and uncontrolled plating may occur in the container holding the solution or on areas of the substrate where plating is not desired. This is likely due to use of sulfur stabilization which is difficult to control and makes the plating solution very sensitive and often times unstable.

In U.S. 2012/0061698 A1, the inventors have used an immersion silver plating bath over electroless nickel to increase solderability in electronics packaging applications. While the method is useful, the silver thickness is limited due to the immersion type reaction and corrosion of the nickel surface is still an issue if the article to be plated is left in the plating solution for extended time.

In International Publication WO 2006/065221 A1 describes an electroless silver plating bath which must operate with two phases present to deposit a uniform silver deposit. The bath is stabilized based on a multi-phase process using non-ionic surfactants where the bath is operated above the cloud point of the surfactants. While the process of this invention results in a desirable deposit, bath control is critical. The bath should be kept warm to prevent decomposition and unwanted deposition, which is not practical when considering commercially viable options.

### SUMMARY OF THE INVENTION

In this invention, stabilizers that contain heavy metal ions were introduced into the electroless silver plating solution which surprisingly addresses the issues found within the prior art, therefore making it possible to move forward with a commercially available process.

Heavy metal based stabilizers allow for precise determination of their concentration within the plating solution, prevent extraneous plating, and reduce the amount of corrosion on the underlying metal surface.

It is therefore an object of the present invention to provide an improved method of plating electroless silver on an article with exposed copper or copper alloy that has been plated with a barrier metal layer prior to plating the article in electroless silver. The inventors have surprisingly discovered that by using a heavy metal based stabilizer, such as lead in an electroless silver plating bath, the underlying nickel layer is not corroded and extraneous plating is eliminated. This is a significant advance since extraneous plating can cause bridging and electrical shorts between finely spaced traces. The use of such metal based stabilizers in the electroless silver plating bath is believed to be responsible for the elimination of any extraneous plating as seen in FIG. 4. Historically, when sulfur based stabilizers are used, extraneous plating is prevalent as seen in FIG. 3. Additionally, the inventors have found that the galvanic corrosion between silver and the substrate was enhanced by using sulfur based stabilizers. Introducing sulfur into the silver deposit can also expedite tarnish of the coating.

In addition to the clear advantages found by using a metal based stabilizer, there are additional benefits over the typical sulfur based stabilizers. The metal based stabilizers can be analyzed and measured in the solution, which is not typically possible when using sulfur based stabilizers due to the low concentration of bath stabilizers along with other interfering organic components. Therefore, the use of heavy metal based stabilizers allows for tighter process control and better bath stability.

It is another object of the present invention to provide an electroless silver plating bath for use over an electroless nickel deposit, in which the nickel corrosion is minimized or eliminated.

It is another object of the present invention to provide control over the stabilizer concentration in the electroless silver plating bath.

It is still another object of the present invention to provide a method of using heavy metal based stabilizers in an electroless silver bath to prevent extraneous plating on areas where plating is not desired.

It is still another object of the present invention to provide an electroless silver plating bath which is stable and not prone to plating out on the vessel in which plating takes place.

To that end, in one embodiment, the present invention relates generally to an electroless silver plating bath and method or using such bath for producing an article that has previously been plated with electroless nickel or electroless cobalt, in which extraneous plating is prevented and the plating bath remains stable, the method comprising, in order, the steps:
a) plating the article with an electroless metal barrier layer;
b) optionally plating an immersion silver strike layer on top of the barrier layer;
c) plating the article in an electroless silver plating composition that comprises a heavy metal based stabilizer, or combinations thereof.

### DESCRIPTION OF THE DRAWINGS

FIG. 1 is a SEM image of a copper pad that was plated with electroless nickel followed by an immersion silver strike layer, and then plated in electroless silver comprising a sulfur based stabilizer. The silver has since been stripped to analyze the amount of corrosion on the nickel surface.

FIG. 2 is a SEM image of a copper pad that has been plated with electroless nickel followed by an immersion silver strike layer, and then plated in electroless silver comprising a heavy metal based stabilizer. The silver has since been stripped to analyze the amount of corrosion on the nickel surface.

FIG. 3 is a microscope image of a ceramic LED test panel plated with electroless nickel followed by electroless silver comprising a sulfur based stabilizer. Extraneous plating is present in the trench areas (space between the traces).

FIG. 4 is a microscope image of a ceramic LED test panel plated with electroless nickel followed by electroless silver comprising a heavy metal based stabilizer. Extraneous plating is not present in the trenches.

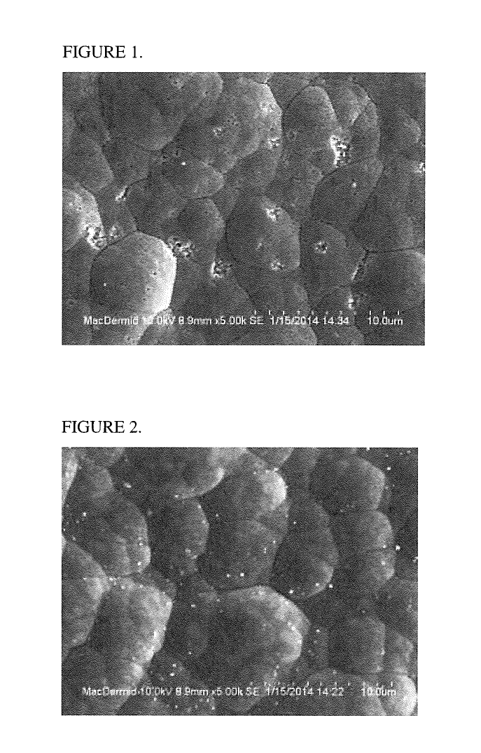

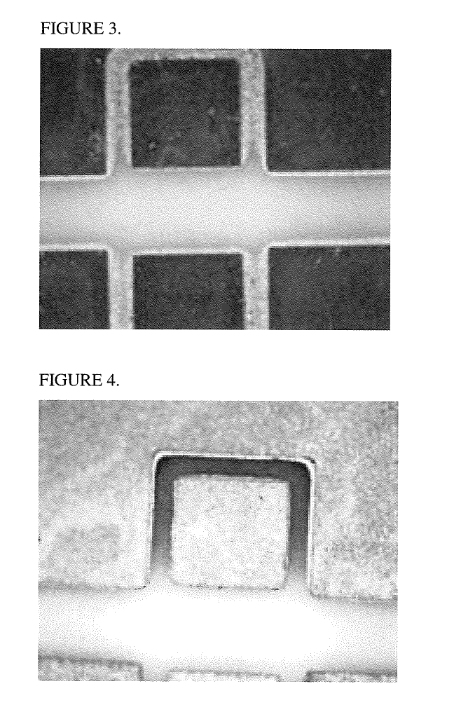

### DETAILED DESCRIPTION OF THE PREFERRED EMBODIMENTS

The inventors of the present invention have found that the use of heavy metal based stabilizers in an electroless silver plating composition can be used to prevent extraneous, control plating rate, and reduce corrosion of the underlying metal surface. Thus, the electroless silver composition described herein allow for controlled electroless plating on metal surfaces exposed on an article without plating on other areas of the article surface, while maintaining a stable bath and not plating out on the vessel walls where the bath is held. In addition, the method described herein can be used to plate in various applications across multiple industries.

To that end, in one embodiment the present invention relates generally to an electroless silver bath which can be used over an electroless metal surface that has previously been plated with a barrier metal such as nickel or cobalt, which prevents extraneous plating while maintaining a stable plating bath. The method of the current invention includes the steps of:
a) plating an electroless metal barrier layer;
b) optionally plating an immersion silver strike layer on top of the barrier layer;
c) plating over the metal barrier layer and optional silver strike layer using an electroless silver bath containing heavy metal based stabilizers, or mixtures thereof.

The inventors of the present invention have found that the inclusion of a heavy metal stabilizers in an electroless silver plating, following the plating of an electroless metal barrier layer and an optional immersion silver strike layer, allows for elimination of extraneous and provide bath stability. While not wishing to be bound by theory, the inventors believe that this is likely due to use of heavy metal based stabilizers which prevents extraneous plating. The ability of the heavy metal ion to aid in bath stability and prevent extraneous plating is both surprising and unexpected.

The problem of extraneous plating and bath plate out, both commonly seen when sulfur stabilizers are used in electroless silver plating baths, is effectively eliminated by using a heavy metal based stabilizer or combinations thereof. The current invention provides an electroless silver bath plating formulation that is useful for plating over an electroless metal barrier layer and an optional immersion silver strike layer. The electroless silver deposit provides desired characteristics such that good wirebonding, good solderability, and high reflectance can all be achieved, all with very little or no corrosion of the underlying electroless metal barrier layer as seen in FIG. 2.

Table 1 presents a rate curve produced by the inventors in which a ceramic LED coupon with exposed copper areas was processed through an electroless nickel bath, followed by an immersion silver strike, and then plated in an electroless silver plating composition of the current invention. As the plating time increased in the electroless silver plating solution, the thickness continued to increase linearly. This indicates that the bath is plating by an electroless mechanism. The thickness continues to increase as plating time increases using the current invention, while if the bath was plating by an immersion reaction the thickness would not continue to grow linearly. An immersion reaction would show a plateau when graphed over time.

A typical process cycle for preparing an article with exposed copper or copper alloy for electroless plating consists of optionally cleaning and/or micro etching the exposed copper or copper alloy, activating using a precious metal catalyst, immersing the article in an acid based solution after activation and then electrolessly plating the areas of exposed copper or copper alloy. A metal barrier layer is created using a first electroless plating bath and then a subsequent electroless silver bath is used to give the final deposit the desired properties.

The metal barrier layer can be either nickel or cobalt which is electrolessly plated over a copper or copper alloy that has been prepared as described above. Any typical electroless nickel or cobalt plating solutions are suitable for use in the current invention. The metal barrier layer may be anywhere from 10-400 microinches thick.

After the electroless metal barrier layer is plated, an immersion silver strike layer may be plated over the barrier layer. This will ensure that any gaps or pores that may be present in the barrier layer will be capped with silver prior to electroless silver plating. The silver strike layer will deposit less than 10 microinches of silver, if used, on top of the metal barrier layer.

The inventors have found that heavy metal based stabilizers or combinations of such compounds, including compounds with metal ions from Group IIIA, Group IVA, Group VA, Group VIA, and the lanthanide series are useful in an electroless silver plating composition.

Examples of these heavy metal based stabilizers that may be used alone or in combination in the current invention are as follows: lead chloride, lead acetate, lead lactate, lead citrate, bismuth citrate, tin sulfate, thallium nitrate, telluric acid, antimony chloride, potassium antimony (III) tartarate, lanthanum (III) nitrate, europium (III) nitrate, indium (III) nitrate, seleneous acid, and sodium selenite.

The heavy metal based stabilizer or combination of such compounds is present in the electroless silver plating composition of the current invention, such that the metal ion is present at a concentration of at least 0.1 mg/L. The metal ion of the heavy metal based stabilizer compound or combination of compounds may be present in total anywhere from 0.1 mg/L-1,000 mg/L. The metal ion of the heavy metal based stabilizer compound or combination of compounds is preferably present anywhere from 0.5 mg/L-100 mg/L, and most preferably from 1 mg/L-10 mg/L.

In addition to the stabilizer compounds as described above, the electroless silver bath comprises at least one source of silver ions, a buffer, a surfactant, a reducing agent, and a complexing agent. Other ingredients may be incorporated as necessary that would be familiar to a skilled artisan. The silver ions are present in the electroless silver composition from 0.1-10 g/L, the buffer is present between 0.1-5 g/L, a surfactant is present between 0.1-5 g/L, the reducing agent is present between 0.1-5 g/L, and the complexing agent(s) is present between 0.1-5 g/L.

The electroless silver bath can be operated at a temperature between 30° C. and 80° C. The bath is more preferably run at an operating temperature between 40° C. and 70° C., and most preferably between 50° C. and 60° C. Plating times are dependent on the desired thickness. The thickness of the silver deposit will increase linearly with the immersion time in the plating composition. A typical deposit may range anywhere from 5-50 microinches, wherein good solderability, good wirebonding and high reflectivity can all be achieved.

The pH of the electroless silver bath should be maintained between 9 and 11, and more preferably between 9.5 and 10.5. The pH is most preferably maintained between 10.1 and 10.4.

The electroless silver bath composition may be utilized with or without a source of air bubbling through the solution.

The amount of stabilizer in solution can easily be analyzed by simple analytical techniques such as titration, using a polaragraph, or by atomic absorption spectroscopy. This is a significant advantage over electroless silver baths that contain sulfur based stabilizers. Sulfur based stabilizers are often difficult to analyze and control once they are in solution due to their low concentration and interference with other organic compounds. In turn, solutions that contain sulfur based stabilizers frequently become either too stable to plate or unstable such that plating rate cannot be controlled, and decomposition of the plating solution occurs. By using a heavy metal based stabilizer, the bath is extremely stable and the plating rate becomes reliably controllable.

The invention as described herein is a novel electroless silver plating composition and method for using the composition. The invention described herein is thought to be useful for a wide variety of applications wherein a final layer of silver can be deposited to provide excellent wirebonding, solderability, and reflectivity. Electroless silver may now be considered useful in commercial applications since the current invention has overcome the long enduring issues of bath stability and extraneous plating (see FIG. 4). This bath additionally provides little to no corrosion of the underlying base metal surface (see FIG. 2). There are many applications which are traditionally plated using the ENIG process which may now may be replaced by the cost efficient and less corrosive process of the current invention. The description of this invention should not be interpreted to be limited to the specific examples included herein, rather the scope should be understood to embody the scope and spirit of the invention as it may be useful in many applications.

1. An electroless silver plating composition comprising:
a. a source of silver ions;
b. a stabilizer comprising a heavy metal ion;
c. a surfactant;
d. a complexor;
e. and a buffer.

2. A composition according to claim 1, wherein the stabilizer consists of a heavy metal ion selected from Group IIIA metals, Group IVA metals, Group VA metals, Group VIA metals, the lanthanide series, and combinations thereof.

3. A composition according to claim 2, wherein the stabilizer is selected from the group consisting of lead chloride, lead acetate, lead lactate, lead citrate, bismuth citrate, tin sulfate, thallium nitrate, telluric acid, antimony chloride, potassium antimony (III) tartarate, lanthanum (III) nitrate, europium (III) nitrate, indium (III) nitrate, seleneous acid, sodium selenite, and combinations thereof.

4. A composition according to claim 3, wherein the stabilizer or combinations thereof, comprises lead.

5. A composition according to claim 3, wherein the stabilizer or combinations thereof, comprises bismuth.

6. A composition according to claim 3, wherein the stabilizer or combinations thereof, comprises antimony.

7. A composition according to claim 1, wherein the concentration of the heavy metal ion in the electroless silver composition is from 0.1 mg/L to 1,000 mg/L.

8. A composition according to claim 7, wherein the concentration of the heavy metal ion in the electroless silver composition is from 0.5 mg/L to 100 mg/L.

9. A composition according to claim 8, wherein the concentration of the heavy metal ion in the electroless silver composition is from 1 mg/L to 10 mg/L.

10. A composition according to claim 1, wherein the pH is between 9 and 11.

11. A composition according to claim 10, wherein the pH is between 9.5 and 10.5.

12. A composition according to claim 11, wherein the pH is between 10.1 and 10.4.

13. A method of plating electroless silver over a metal barrier layer comprising the steps:
a) optionally preparing a copper or copper alloy for plating;
b) plating a copper or copper alloy with a metal barrier layer using electroless nickel or electroless cobalt,
c) optionally providing an immersion silver strike layer over the metal barrier layer; and then
d) plating electroless silver using an electroless silver composition over the metal barrier layer and optional strike layer;
wherein the electroless silver composition contains a stabilizer that comprises heavy metal ions.

14. The method according to claim 13, wherein the stabilizer consists of a heavy metal ion selected from Group IIIA metals, Group IVA metals, Group VA metals, Group VIA metals, the lanthanide series, and combinations thereof.

15. The method according to claim 14, wherein the stabilizer is selected from the group consisting of lead chloride, lead acetate, lead lactate, lead citrate, bismuth citrate, tin sulfate, thallium nitrate, telluric acid, antimony chloride, potassium antimony (III) tartarate, lanthanum (III) nitrate, europium (III) nitrate, indium (III) nitrate, seleneous acid, sodium selenite, and combinations thereof.

16. The method according to claim 15, wherein the stabilizer or combinations thereof, comprises lead.

17. The method according to claim 15, wherein the stabilizer or combinations thereof, comprises bismuth.

18. The method according to claim 15, wherein the stabilizer or combinations thereof, comprises antimony.

19. The method according to claim 13, wherein the concentration of the heavy metal ion in the electroless silver composition is from 0.1 mg/L to 1,000 mg/L.

20. The method according to claim 19, wherein the concentration of the heavy metal ion in the electroless silver composition is from 0.5 mg/L to 100 mg/L.

21. The method according to claim 20, wherein the concentration of the heavy metal ion in the electroless silver composition is from 1 mg/L to 10 mg/L.

22. The method according to claim 13, wherein the barrier layer metal is nickel.

23. The method according to claim 13, wherein the electroless silver composition does not cause extraneous plating.

24. The method according to claim 13, wherein the electroless silver plating rate increases linearly with immersion time.

25. The method according to claim 13, wherein the electroless silver plating composition has a pH between 9 and 11.

26. The method according to claim 25, wherein the electroless silver plating composition has a pH between 9.5 and 10.5.

27. The method according to claim 26, wherein the electroless silver plating composition has a pH between 10.1 and 10.4.

28. A method for plating a copper or copper alloy exposed on an article using an electroless silver composition comprising the steps of:
a) optionally cleaning, etching, and activating the exposed copper or copper alloy;
b) plating the exposed copper or copper alloy with a barrier layer using an electroless plating bath comprising nickel or cobalt;
c) optionally plating an immersion silver strike layer on top of the barrier layer;
d) plating an electroless silver deposit on top of the barrier layer and optional silver strike layer;
wherein the electroless silver composition comprises heavy metal ions.
